(19) United States
(12) Patent Application Publication
(10) Pub. No.: US 2025/0246507 A1
(43) Pub. Date: Jul. 31, 2025

(54) SEMICONDUCTOR DEVICE, SEMICONDUCTOR PACKAGE AND MANUFACTURING METHOD OF SEMICONDUCTOR DEVICE

(71) Applicant: Taiwan Semiconductor Manufacturing Company, Ltd., Hsinchu (TW)

(72) Inventors: Han-Jong Chia, Hsinchu City (TW); Yu-Jen Lien, Tainan City (TW); Ke-Han Shen, Chiayi City (TW); Cheng-Chieh Hsieh, Tainan (TW); Kuo-Chung Yee, Taoyuan City (TW); Szu-Wei Lu, Hsinchu City (TW); Chung-Ju Lee, Hsinchu City (TW); Chen-Hua Yu, Hsinchu City (TW); Ji CUI, Bolingbrook, IL (US); Chih-Ming Ke, Hsinchu City (TW); Hung-Yi Kuo, Taipei City (TW)

(73) Assignee: Taiwan Semiconductor Manufacturing Company, Ltd., Hsinchu (TW)

(21) Appl. No.: 18/426,140

(22) Filed: Jan. 29, 2024

(51) Int. Cl. H01L 23/373; H01L 21/56; H01L 23/00; H01L 25/065; H01L 25/18; H01L 27/12

(52) U.S. Cl. CPC H01L 23/3732; H01L 21/56; H01L 24/05; H01L 24/08; H01L 24/13; H01L 25/0657; H01L 25/18; H10D 86/441; H10D 86/60; H01L 24/14; H01L 2224/05567; H01L 2224/08145; H01L 2224/13021; H01L 2224/13109; H01L 2224/13111; H01L 2224/13116; H01L 2224/13124; H01L 2224/13139; H01L 2224/13144; H01L 2224/13147; H01L 2224/13155; H01L 2224/13164; H01L 2224/1403; H01L 2224/14051; H01L 2225/06541; H01L 2225/06548

(57) ABSTRACT

A semiconductor device includes a first interconnect structure, a device layer, a second interconnect structure, a diamond layer, a passivation layer, and an electrical connector. The device layer is disposed over the first interconnect structure. The second interconnect structure is disposed over the device layer and comprises a topmost metallization pattern. The diamond layer is disposed over the second interconnect structure and at least revealing a part of the topmost metallization pattern. The passivation layer covers the diamond layer and reveals the part of the topmost metallization pattern. The electrical connector is disposed over the passivation layer and bonded to the part of the topmost metallization pattern.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (POP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 6 illustrate cross sectional views of intermediate stages in the manufacturing of a semiconductor device according to some exemplary embodiments of the present disclosure.

FIG. 7 to FIG. 13 illustrate cross sectional views of intermediate stages in the manufacturing of the structure in section A of FIG. 6 according to some exemplary embodiments of the present disclosure.

FIG. 14 to FIG. 15 illustrate cross sectional views of intermediate stages in the manufacturing of a diamond layer in a semiconductor device according to other exemplary embodiments of the present disclosure.

FIG. 16 illustrates a cross sectional view of a semiconductor package according to some exemplary embodiments of the present disclosure.

FIG. 17 illustrates a cross sectional view of a semiconductor package according to other exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide semiconductor devices and semiconductor packages having improved heat dissipation efficiency and methods of forming the same. These embodiments applied to, but not limited to, the formation of a semiconductor device with power rail on its backside and a diamond layer on its backside or front side to facilitate heat dissipation. In some embodiments, the power rail may be a metal line that is coupled to a reference voltage, positive supply voltage, or the like, and in some instances, and may be used to provide power to a transistor. Advantageous features of one or more embodiments disclosed herein may include the ability to increase the heat dissipation efficiency and heat dissipation paths by adding diamond layer on the backside and/or front side of the semiconductor device so the heat can be dissipated through the diamond layer.

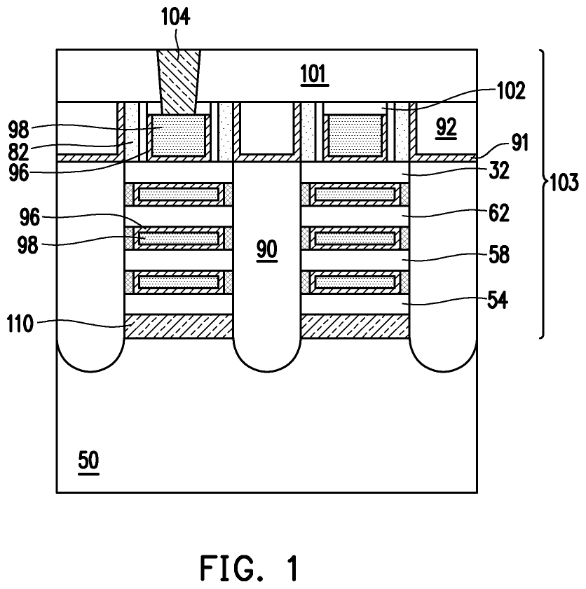

FIG. 1 to FIG. 6 illustrate cross sectional views of intermediate stages in the manufacturing of a semiconductor device according to some exemplary embodiments of the present disclosure. In some embodiments, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Then, a device layer 103 is formed over a semiconductor substrate 50. In some embodiments, the device layer 103 may be a multi-layer stack. The multi-layer stack may include any number of channel layers, sacrificial layers, etc. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, alternating layers of the multi-layer stack may be formed of first semiconductor materials (e.g., silicon (Si), silicon carbon (SiC), or the like) or second semiconductor materials (e.g., silicon germanium (SiGe) or the like).

In one embodiment, fins may be formed in the device layer 103 and the substrate 50. The fins may be semiconductor strips. In some embodiments, the fins may be formed in the device layer 103 and the substrate 50 by etching trenches in the device layer 103 and the substrate 50. The etching may be any acceptable etch process, such as a reactive ion etch (RIE), neutral beam etch (NBE), the like, or a combination thereof. The etching may be anisotropic. In some embodiments, a dielectric layer 110 may extend between the substrate 50 and the channel layer 54. The dielectric layer 110 is used to isolate the gates and the channel layers (e.g., the channel layer 54, channel layer 58, channel layer 62, and channel layer 32) of the nano-FETs from the substrate 50, which prevents short circuiting between the gates and a subsequently formed power rail 124 (discussed below with respect to FIG. 5).

In some embodiments, the source/drain regions 90 may be formed by epitaxially growing any acceptable material. A first interlayer dielectric (ILD) 92 is deposited over the structure. The first ILD 92 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 91 is disposed between the first ILD 92 and the source/drain regions 90, and the gate spacers 82. The CESL 91 may include a dielectric material, such as, silicon nitride, silicon oxide, silicon oxynitride, or the like, having a different etch rate than the material of the overlying first ILD 92.

The gate electrodes 98 are deposited over the gate dielectric layers 96, respectively. The gate electrodes 98 may include a metal-containing material such as titanium nitride, titanium oxide, tantalum nitride, tantalum carbide, cobalt, ruthenium, aluminum, tungsten, combinations thereof, or multi-layers thereof. For example, although a single layer gate electrode 98 is illustrated herein, the gate electrodes 98 may include any number of liner layers, any number of work function tuning layers, and a fill material. The gate electrodes 98 may be formed by ALD, CVD, PVD, the like, or combinations thereof. In some embodiments, the gate electrodes 98 may be formed by ALD followed by PVD.

In some embodiments, a gate mask 102 including one or more layers of dielectric material, such as silicon nitride, silicon oxynitride, or the like, is filled in the recess, followed by a planarization process to remove excess portions of the dielectric material extending over the first ILD 92. Subsequently formed gate contacts 104 penetrate through the gate mask 102 to contact the top surface of the recessed gate electrodes 98.

Then, the gate contacts 104 are formed. The gate contacts 104 may be physically and electrically coupled to a bottommost metallization pattern 118 in a subsequently formed interconnect structure 112 (discussed below with respect to FIG. 24). Openings for the gate contacts 104 are formed through the second ILD 101 and the gate mask 102. The openings may be formed using acceptable photolithography and etching techniques. A liner, such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 101. The remaining liner and conductive material form the gate contacts 104 in the openings. The gate contacts 104 are physically and electrically coupled to the gate electrodes 98. It is noted that the structure of the device layer 103 herein is merely for illustration purpose. The disclosure does not limit the configurations and components of the device layer.

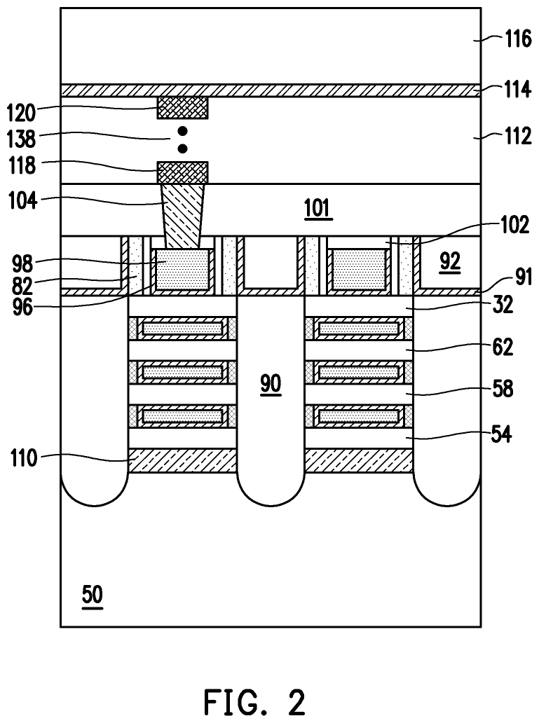

Then, referring to FIG. 2, a (first) interconnect structure 112 may be formed over a first side (i.e., front side) of the device layer 103. To be specific, the first interconnect structure 112 may be formed on the second ILD 101. In some embodiments, the first interconnect structure 112 includes electrical routing 138 formed over the second ILD 101. The electrical routing 138 may be formed of one or more layers of conductive lines in a dielectric (e.g., low-k dielectric material) material with conductive vias interconnecting the layers of conductive lines. For example, the electrical routing 138 may include one to three layers of conductive lines. In other embodiments, the electrical routing 138 may include a different number of layers of conductive lines. The conductive vias may extend through the dielectric to provide vertical connections between layers of conductive lines. The electrical routing 138 may be formed through any suitable process (such as deposition, damascene, dual damascene, or the like).

In some embodiments, the electrical routing 138 is formed using a damascene process in which a respective dielectric layer is patterned and etched utilizing photolithography techniques to form trenches corresponding to the desired pattern of metallization layers and/or vias. An optional diffusion barrier and/or optional adhesion layer may be deposited and the trenches may be filled with a conductive material. Suitable materials for the barrier layer includes titanium, titanium nitride, titanium oxide, tantalum, tantalum nitride, titanium oxide, or other alternatives, and suitable materials for the conductive material include copper, silver, gold, tungsten, aluminum, combinations thereof, or the like. In an embodiment, the electrical routing 138 may be formed by depositing a seed layer of copper or a copper alloy, and filling the trenches by electroplating. A chemical mechanical planarization (CMP) process or the like may be used to remove excess conductive material from a surface of the respective dielectric layer and to planarize the surface for subsequent processing.

In FIG. 2, a topmost metallization pattern 120 and a bottommost metallization pattern 118 in the interconnect structure 112 are illustrated. However, it should be appreciated that the interconnect structure 112 may include any number of metallization patterns disposed in any number of dielectric layers. Interconnect structure 112 may be electrically connected to gate contacts 104.

Then, a carrier substrate 116 is bonded to a top surface of the interconnect structure 112 using a suitable technique such as dielectric-to-dielectric bonding, or the like. The carrier substrate 116 may be a glass carrier substrate, a ceramic carrier substrate, a wafer (e.g., a silicon wafer), or the like.

In various embodiments, the carrier substrate 116 may be bonded to the interconnect structure 112 using a suitable technique such as dielectric-to-dielectric bonding, or the like. Dielectric-to-dielectric bonding may include the use of a bonding layer (not shown) on a top surface of interconnect structure 112 and a bottom surface of carrier substrate 116, respectively. In some embodiments, the bonding layer may each include silicon oxide formed on the top surface of the interconnect structure 112 and the bottom surface of the carrier substrate 116, respectively by a deposition process, such as chemical vapor deposition (CVD), physical vapor deposition (PVD), or the like. In other embodiments, the bonding layer may be formed by the thermal oxidation of a silicon surface on the carrier substrate 116. In alternative embodiments, the bonding layer may include silicon oxynitride, silicon nitride, or the like.

In some embodiments, an auxiliary diamond layer 114 is disposed between the carrier substrate 116 and the first interconnect structure 112 for heat dissipation. To be specific, the auxiliary diamond layer 114 may be disposed between the bonding layer on the carrier substrate 116 and the first interconnect structure 112. Unlike most electrical insulators, diamond is a good conductor of heat because of the strong covalent bonding and low phonon scattering. Thermal conductivity of natural diamond was measured to be about 2,200 W/(m·K), which is five times more than silver, the most thermally conductive metal. Accordingly, by disposing the auxiliary diamond layer 114 with such high thermal conductance, the heat generated from the device layer 103 during operation can be transmitted through the metallization pattern in the first interconnect structure 112 to the auxiliary diamond layer 114 and be dissipated therefrom, so as to prevent silicon and/or other semiconducting materials from overheating. The high thermal conductivity of the auxiliary diamond layer 114 is used for the efficient heat removal in semiconductor devices such as high-end power electronics.

In one embodiment, there are different methods for providing the auxiliary diamond layer 114 between the carrier substrate 116 and the first interconnect structure 112. For example, a diamond wafer may be firstly attached to the first interconnect structure 112. Then, a thinning process is performed to form the auxiliary diamond layer 114, and the auxiliary diamond layer 114 can then be attached to the carrier substrate 116 through, for example, a bonding film. The thinning process may include grinding or chemical-mechanical polishing (CMP) processes, etch back processes, or other acceptable processes performed on the surface of the auxiliary diamond layer 114. In some embodiments, the auxiliary diamond layer 114 can be thinned to be at least equal to or smaller than about 20 μm. In one embodiments, the thickness of the auxiliary diamond layer 114 is substantially equal to or smaller than about 5 μm. If the auxiliary diamond layer 114 is too thick (e.g., thicker than 5 μm), stress concentration may be severe, which may lead to die breakage or die crack, due to hardness of diamond (diamond is the hardest known naturally occurring material, and serves as the definition of 10 on the Mohs scale of mineral hardness).

In another embodiment of providing the auxiliary diamond layer 114 between the carrier substrate 116 and the first interconnect structure 112, a diamond layer may be firstly deposited over the first interconnect structure 112, and a planarizing process is then performed to the diamond layer to form the auxiliary diamond layer 114 with a flat surface. Then, the carrier substrate 116 can be attached to the auxiliary diamond layer 114 through the bonding film. In some embodiments, the planarizing process may include grinding or CMP processes, or other acceptable processes performed on the surface of the auxiliary diamond layer 114, and the auxiliary diamond layer 114 can also be thinned to a predetermined thickness (e.g., thinner than 5 μm) through the planarizing process.

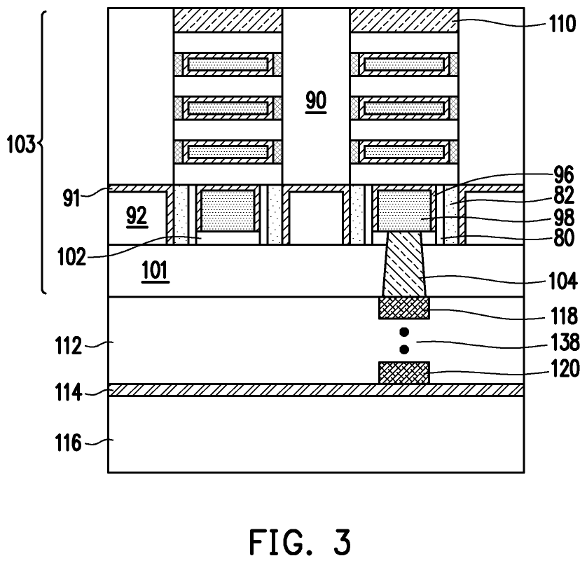

Referring to FIG. 2 and FIG. 3, the resulting structure shown in FIG. 2 is then flipped over so that a surface of the substrate 50 is exposed. Then, a thinning process may be applied to the substrate 50. The thinning process may include grinding or CMP processes, etch back processes, or other acceptable processes performed on the surface of the substrate 50. The thinning process may expose the STI regions, gate dielectric layers, dielectric layer 110, and the source/drain regions 90. During the thinning process, a CMP process may be used that has different CMP selectivity for the heavily doped p-type region, the lightly doped p-type region, and the silicon-germanium layer. The dopant concentration and type of material may influence the removal rate during the CMP process and hence, the removal rate can be controlled to achieve a desired final thickness. After the planarization process, top surfaces of the dielectric layer 110 and the source/drain regions 90 are level with one another. After this thinning process, the dielectric layer 110 may have a thickness in the range of between, for example, about 6 nm to 20 nm. Providing a dielectric layer 110 having this thickness may have advantages. For example, providing a thinner dielectric layer 110 (e.g., thinner than 6 nm) may lead to insufficient isolation being provided by the dielectric layer 110 between the channel layers of the nano-FETs and the substrate 50. This insufficient isolation may cause gate to power rail short circuiting. Providing a thicker dielectric layer 110 (e.g., thicker than 20 nm) may require an inefficiently thick dielectric layer 132 to be deposited, which increases manufacturing costs and reducing yield.

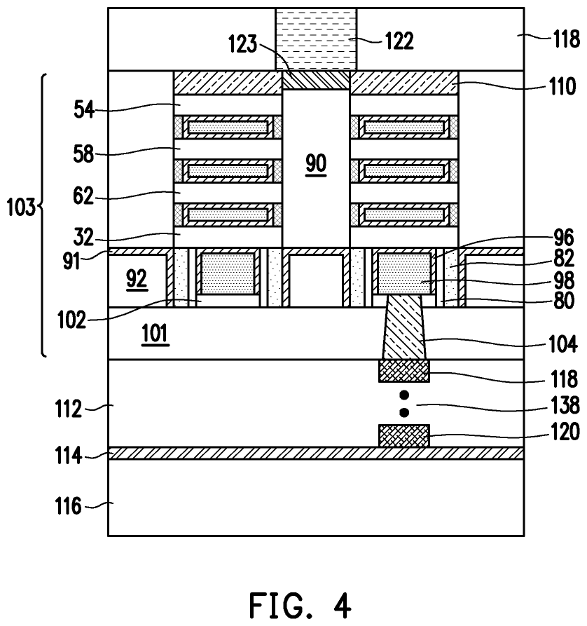

Referring to FIG. 4, an isolation layer 118 is deposited over the dielectric layer 110 and the source/drain regions 90. The isolation layer 118 may be formed of a dielectric material, and may be deposited by any suitable method, such as CVD, plasma-enhanced CVD (PECVD), or the like. The isolation layer 118 may include silicon oxide, silicon oxynitride, silicon nitride, or the like. An opening for the subsequently formed contact via 122 is formed through the isolation layer 118. The opening 160 may be formed using acceptable photolithography and etching techniques.

In some embodiments, a contact via 122 is formed. The contact via 122 may include a liner, such as a diffusion barrier layer, an adhesion layer, or the like, and a conductive material in the opening. The liner is deposited first, and may include titanium, titanium nitride, tantalum, tantalum nitride, or the like. Next, the opening is filled with the conductive material. The conductive material may be copper, a copper alloy, silver, gold, tungsten, cobalt, aluminum, nickel, or the like. The contact via 122 has bottom portions that overlap top surfaces of the dielectric layer 110 and is physically and electrically coupled to the source/drain regions 90. A planarization process, such as a CMP, may be performed to remove excess conductive material from a surface of the isolation layer 118 such that a top surface of the contact via 122 and a top surface of the isolation layer 118 are level with one another. An anneal process may be performed to form a silicide region 123 at the interface between the contact via 122 and the epitaxial source/drain regions 90. The dielectric layer 110 provides insulation such that the contact via 122 may overlap the channel layer 54. Consequently, the contact area of contact via 122 can be enlarged (e.g., larger than the width of the source/drain regions 90), which improves alignment tolerance, increases manufacturing efficiency, and reduces defects. In addition, the dielectric layer 110 prevents short circuiting between the channel layers of the nano-FETs and a subsequently formed power rail 124 (discussed below with respect to FIG. 5) by isolating the contact via 122 from the channel layers (e.g., channel layer 54, channel layer 58, channel layer 62, and channel layer 32).

In FIG. 5, a power rail 124 is formed over a second side (e.g., backside) of the device layer 103. The power rail 124 is formed by depositing a conductive material over the structure illustrated in FIG. 4. In some embodiments, the power rail 124 includes a metal layer, which may be a single layer or a composite layer comprising a plurality of sub-layers formed of different materials. In some embodiments, the power rail 124 includes copper, aluminum, cobalt, tungsten, titanium, tantalum, ruthenium, or the like. The power rail 124 may be formed using, for example, PVD, plating or the like. The power rail 124 is physically and electrically coupled to the source/drain regions 90 through the contact via 122. Subsequently, a planarization process (e.g., a CMP, grinding, etch back, or the like) may be performed on a surface 162 of the power rail 124. As a result of this thinning process, the power rail 124 may have a thickness Tl in a range of between about 10 nm to about 20 nm. As illustrated in FIG. 5, a portion of the semiconductor device between the interconnect structure 112 and the power rail 124 is referred to as the device layer 103.

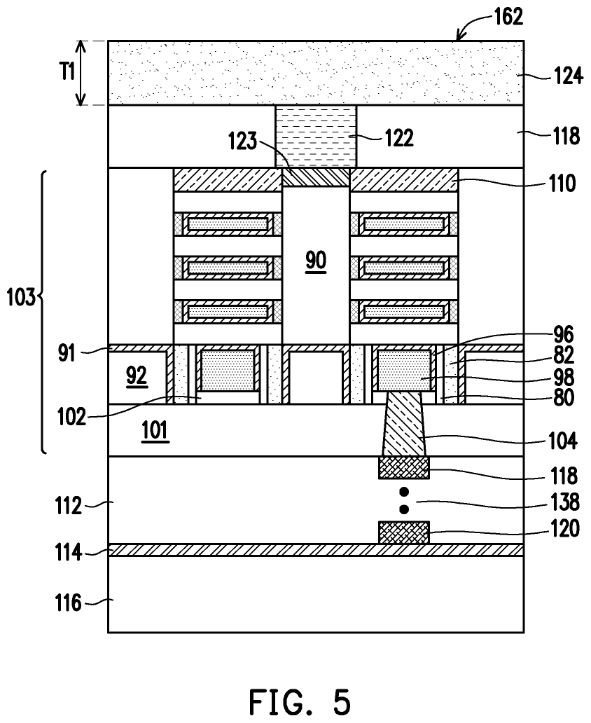

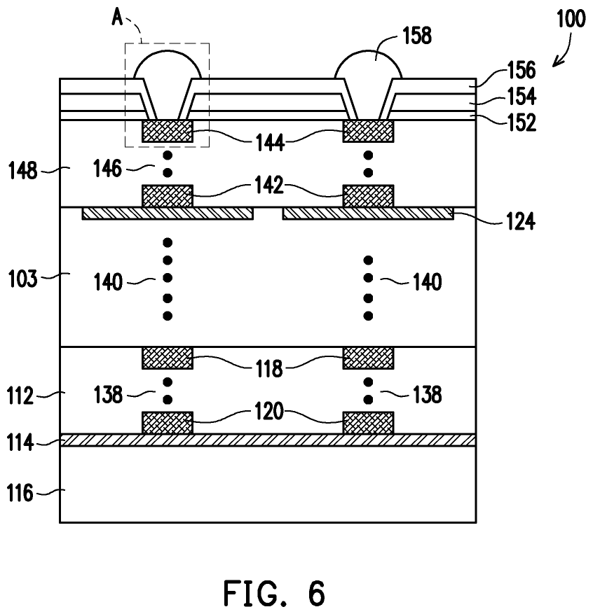

In FIG. 6, a second interconnect structure 148 may be formed over the device layer 103 (which was described earlier in FIG. 29) and bonded to the power rail 124. In some embodiments, the interconnect structure 148 includes electrical routing formed over the device layer 103 and the power rail 124. The electrical routing 146 may be formed of one or more layers of conductive lines in a dielectric (e.g., low-k dielectric material) material with conductive vias interconnecting the layers of conductive lines. For example, the electrical routing 146 may include one to three layers of conductive lines. In other embodiments, the electrical routing 146 may include a different number of layers of conductive lines. The conductive vias may extend through the dielectric to provide vertical connections between layers of conductive lines. The electrical routing 146 may be formed through any suitable process (such as deposition, damascene, dual damascene, or the like).

In some embodiments, the electrical routing 146 is formed using a damascene process in which a respective dielectric layer is patterned and etched utilizing photolithography techniques to form trenches corresponding to the desired pattern of metallization layers and/or vias. An optional diffusion barrier and/or optional adhesion layer may be deposited and the trenches may be filled with a conductive material. Suitable materials for the barrier layer includes titanium, titanium nitride, titanium oxide, tantalum, tantalum nitride, titanium oxide, or other alternatives, and suitable materials for the conductive material include copper, silver, gold, tungsten, aluminum, combinations thereof, or the like. In an embodiment, the metallization layers may be formed by depositing a seed layer of copper or a copper alloy, and filling the trenches by electroplating. A chemical mechanical planarization (CMP) process or the like may be used to remove excess conductive material from a surface of the respective dielectric layer and to planarize the surface for subsequent processing.

In FIG. 6, a topmost metallization pattern 144 and a bottommost metallization pattern 142 in the second interconnect structure 148 are illustrated. However, it should be appreciated that the interconnect structure 148 may include any number of metallization patterns disposed in any number of dielectric layers. Then, a diamond layer 152, a passivation layer 154, a dielectric layer 156, and at least one electrical connector 158 are sequentially formed over the second interconnect structure 148 to form the semiconductor device 100 shown in FIG. 6. The diamond layer 152 is formed over the second interconnect structure 148, and at least reveals a part of the topmost metallization pattern 144. The passivation layer 154 is formed over the diamond layer 152, and the passivation layer 154 reveals the part of the topmost metallization pattern 144 that is revealed by the diamond layer 152. The dielectric layer 156 covers the passivation layer 154. Then, at least one electrical connector 158 is formed over the passivation layer 154 and the dielectric layer 156, wherein the electrical connector 158 is bonded to the part of the topmost metallization pattern 144 through the openings of the diamond layer 152, the passivation layer 154 and the dielectric layer 156. After the electrical connector 158 is formed over the passivation layer 154 and bonded to the part of the topmost metallization pattern 144, the manufacturing of the semiconductor device 100 may be substantially done. The manufacturing process of the structure shown in Section A of FIG. 6 will be described in detail below.

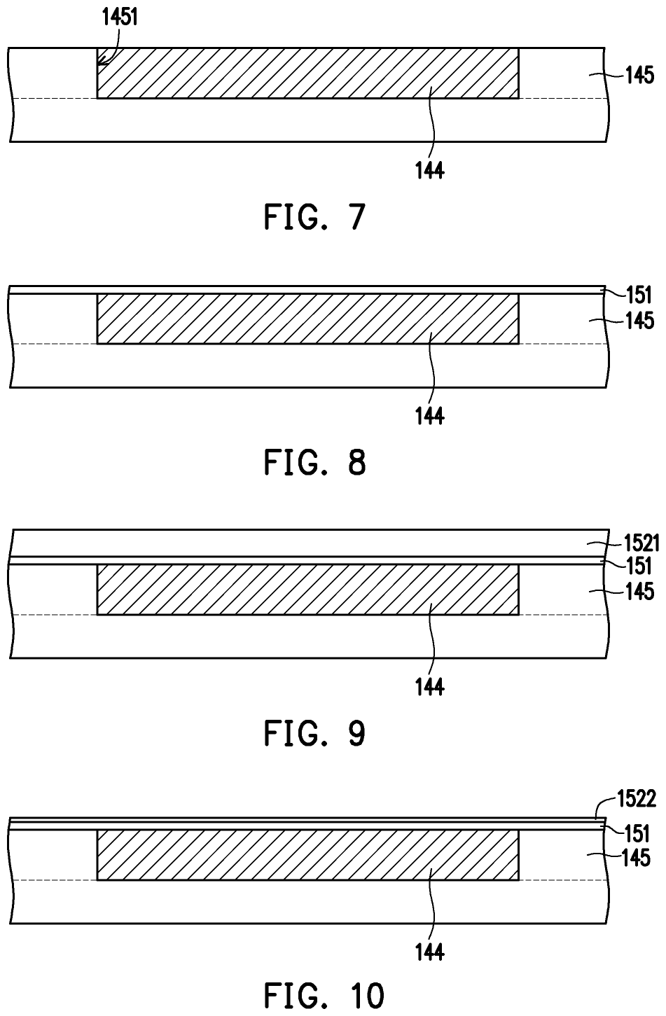

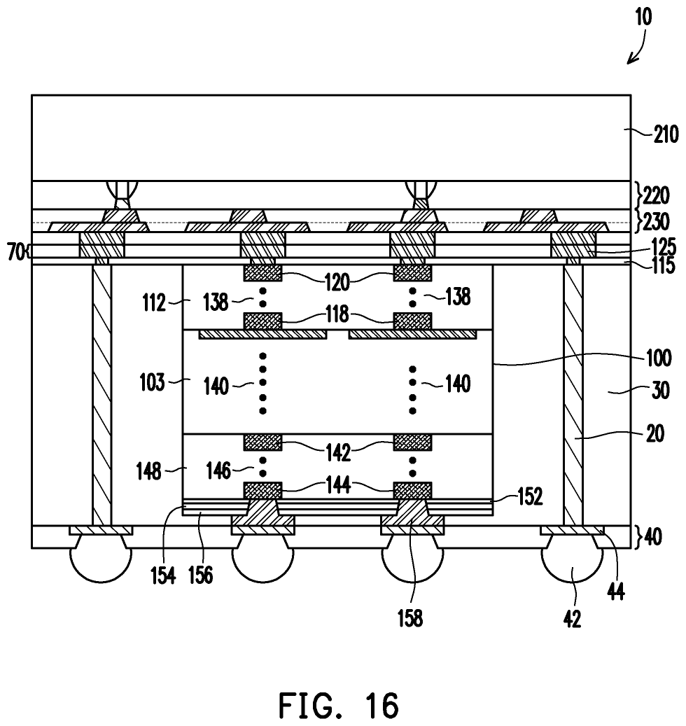

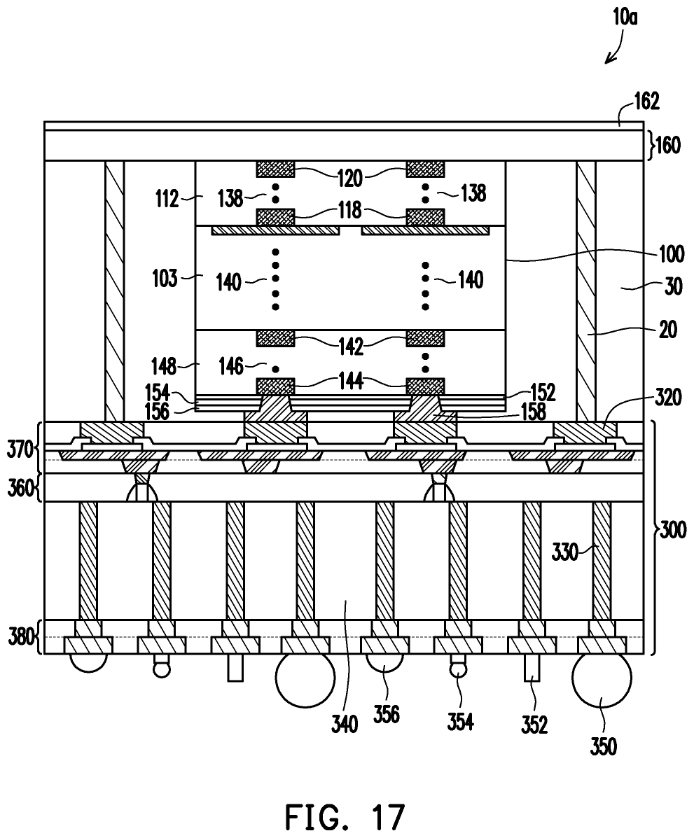

FIG. 7 to FIG. 13 illustrate one of the possible methods of forming the structure shown in Section A of FIG. 6, but the disclosure is not limited thereto. Referring to FIG. 6 and FIG. 7, in some embodiments, the second interconnect structure 148 includes a plurality of metallization pattern layers such as illustrated in FIG. 6, and the topmost metallization pattern 144 includes a plurality of bonding pads which may include a conductive material such as, e.g., copper, titanium, tungsten, aluminum, or the like to which external connections are made. In detail, a dielectric layer 145 is formed over second interconnect structure 148 and the topmost metallization pattern 144, also referred to as the bonding pads 144, are formed over and electrically connected to the electrical routing 146 for providing electrical connection of the device layer 103 to subsequently attached devices (see below, FIG. 16 and FIG. 17). The dielectric layer 145 may be a dielectric material such as SiCN and/or an oxide, e.g. silicon oxide, or the like. The dielectric layer 145 may be formed, for example, by spin coating, lamination, chemical vapor deposition (CVD), or the like. However, any suitable method or materials may be used. A plurality of openings 1451 extend through the dielectric layer 145 to the bonding pads 144 for revealing the bonding pads 144 underneath.

In some embodiments, the bonding pads 144 may be formed with a damascene process in which the dielectric layer 145 is patterned and etched utilizing photolithography techniques to form trenches corresponding to the desired pattern of conductive pads. In some embodiments, the bonding pads 144 are formed with a dual damascene process with vias disposed between the electrical routing 146 and the bonding pads 144. An optional diffusion barrier and/or optional adhesion layer may be deposited and the trenches may be filled with a conductive material. Suitable materials for the diffusion barrier layer includes titanium, titanium nitride, titanium oxide, tantalum, tantalum nitride, titanium oxide, or other alternatives, and suitable materials for the conductive material include copper, silver, gold, tungsten, aluminum, combinations thereof, or the like. In an embodiment, the conductive pads 66 may be formed by depositing a seed layer of copper or a copper alloy, and filling the trenches by electroplating. A chemical mechanical planarization (CMP) process or the like may be used to remove excess conductive material from a surface of the dielectric layer 145 and to planarize the surface for subsequent processing.

Referring to FIG. 6 and FIG. 8, a bonding film 151 is formed over the second interconnect structure 148. To be specific, the bonding film 151 is formed on the dielectric layer 145 and the topmost metallization pattern 144. In some embodiments, the bonding film 151 may include silicon oxide formed on the top surface of the second interconnect structure 148 by a deposition process, such as chemical vapor deposition (CVD), physical vapor deposition (PVD), or the like. In alternative embodiments, the bonding film 151 may include silicon oxynitride, silicon nitride, or the like, but the disclosure is not limited thereto.

Then, referring to FIG. 6 and FIG. 9, a diamond wafer 1521 is attached over the second interconnect structure 148 through the bonding film 151. In some embodiments, the diamond wafer 1521 may be referred to a bulk of diamond or a wafer with a diamond film on its surface. In the embodiment, the diamond wafer 1521 may include a substrate and a diamond film deposited over the substrate through, for example, chemically vapor deposition (CVD) process, plasma-Enhanced CVD (PECVD), microwave plasma enhanced chemical vapor deposition (MWCVD), etc.

Then, referring to FIG. 9 and FIG. 10, a thinning process is performed to form a thinned diamond wafer 1522. The thinning process may include grinding or chemical-mechanical polishing (CMP) processes, etch back processes, or other acceptable processes performed on the surface of the diamond wafer 1521, so as to remove the substrate and a part of the diamond film. In some embodiments, the thickness of the thinned diamond wafer 1522 may be at least equal to or smaller than about 20 μm. In one embodiments, the thickness of the thinned diamond wafer 1522 is substantially equal to or smaller than about 5 μm. If the thinned diamond wafer 1522 is too thick (e.g., thicker than 5 μm), stress concentration may be severe, which may lead to die breakage or die crack, due to hardness of diamond.

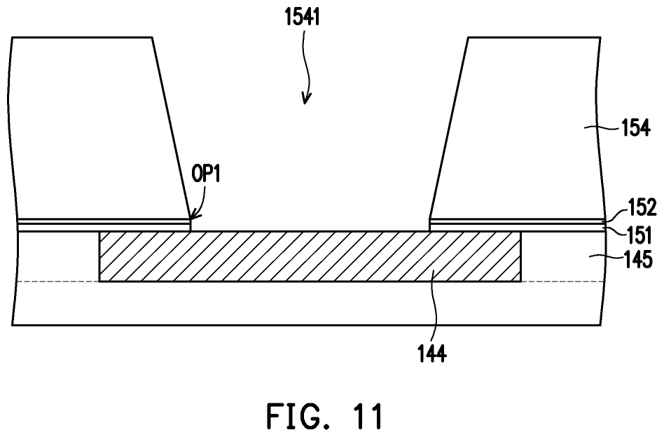

Then, referring to FIG. 10 and FIG. 11, a patterning process is performed on the thinned diamond wafer 1522 and the bonding film 151 to form the diamond layer 152 and the bond film 151 that reveal a part of the topmost metallization pattern 144 (e.g., the bonding pad 144). In some embodiments, at least one opening OP1 is formed by the patterning process, and the opening OP1 extends through the diamond layer 152 and the bonding film 151 to reveal a part of the bonding pad 144 underneath. In some embodiments, the patterning process may include etching (dry etching) process, laser process, or the like. The laser process may adopt a laser such as a YAG, CO₂, excimer laser, or the like. The disclosure is not limited thereto.

Then, a passivation layer 154 is formed over the diamond layer 152. In the embodiment, the passivation layer 154 may include high-k dielectric layer such as hafnium oxide (HfO₂). Alternatively, the high-k dielectric layer may include other high-k dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr) TiO₃ (BST), Al₂O₃, Si₃N₄, oxynitrides (SiON), combinations thereof, or other suitable dielectric material. The passivation layer 154 may be formed by ALD, physical vapor deposition (PVD), oxidation, and/or other suitable methods. Then, at least one opening 1541 corresponding to the opening OP1 is formed by the patterning process, and the opening 1541 extends through the passivation layer 154 to reveal the part of the bonding pad 144 that is revealed (exposed) by the diamond layer 152 and the bonding film 151. In other embodiments, the passivation layer 154 may be formed over the thinned diamond wafer 1522 before the opening OP1 is formed, and a patterning process is formed to form the opening extending through the thinned diamond wafer 1522, the bonding film 151, and the passivation layer 154 all at once. The disclosure is not limited thereto.

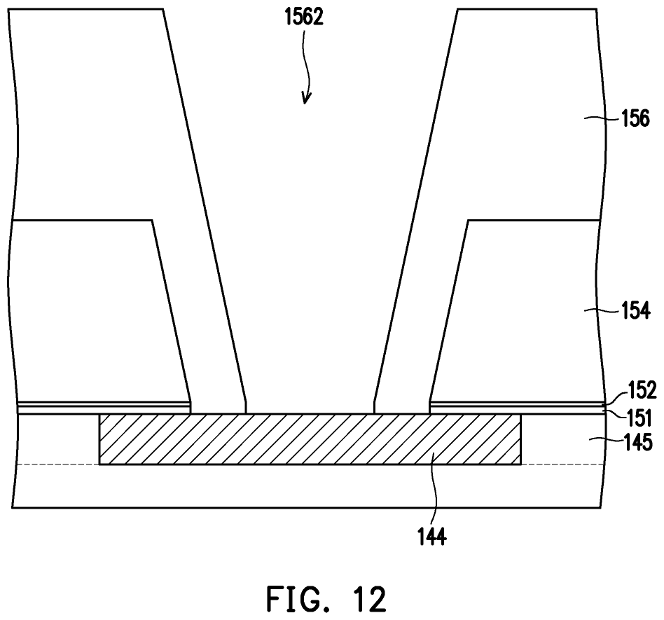

Then, referring to FIG. 12, a dielectric layer 156 is formed to cover the passivation layer 154. The dielectric layer 156 may include polymers such as PBO, polyimide, BCB, or the like. Alternatively, the dielectric layer 150 may include non-organic dielectric materials such as silicon oxide, silicon nitride, silicon carbide, silicon oxynitride, or the like. Then, at least one opening 1562 corresponding to the opening OP1 and the opening 1541 is formed by the patterning process, and the opening 1562 extends through the dielectric layer 156 to reveal a part of the bonding pad 144 that is revealed (exposed) by the diamond layer 152, the bonding film 151, and the passivation layer 154. In some embodiments, the size of the opening 1562 may be slightly smaller than the size of the openings OP1 and 1541, which means the dielectric layer 156 may cover (in contact with) the sidewall of the opening s OP1 and 1541 and a part of the bonding pad 144. In other embodiments, the size of the opening 1562 may be slightly smaller than the size of the openings OP1 and 1541, which means the dielectric layer 156 may cover (in contact with) the inner sidewall of the openings OP1 and 1541 and a part of the bonding pad 144.

Then, at least one electrical connector 158 is provided over the passivation layer 154 and the dielectric layer 156, and the electrical connector 158 is bonded to the part of the topmost metallization pattern 144 through the openings 1562, 1541, and OP1. The formation of electrical connectors 154 may include placing solder balls on the exposed portions of topmost metallization pattern 144 and then reflowing the solder balls. In alternative embodiments, the formation of electrical connectors 154 includes performing a plating step to form solder regions over the topmost metallization pattern 144 and then reflowing the solder regions. The electrical connectors 154 may also include metal pillars, or metal pillars and solder caps, which may also be formed through plating. The electrical connectors 154 may be electrically connected to one or more power rails 124.

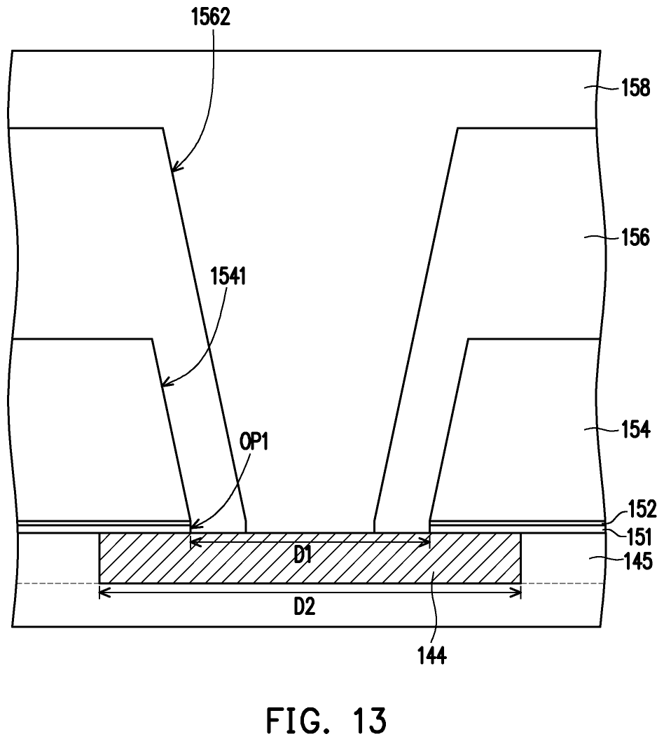

Referring to FIG. 6 and FIG. 13, With such configuration, by disposing the diamond layer 152 with such high thermal conductivity, the heat generated from the device layer 103 during operation can be transmitted through the metallization pattern in the second interconnect structure 148 to the diamond layer 152 and then be further conducted to the electrical connector 158 and dissipated therefrom, so as to prevent the device from overheating. Moreover, the diamond layer 152 is extended through the surface of the dielectric material, so as to increase the heat dissipation area of the device and facilitate the heat dissipation efficiency of the device. In some embodiments, the size (e.g., diameter) D1 of the opening OP1 of the diamond layer 152 is smaller than the size (e.g., diameter) D2 of the bonding pad 144, so the diamond layer 152 covers a peripheral region of the bonding pad 144. In other words, the diamond layer 152 overlap with a peripheral region of the bonding pad 144 from a top view. Accordingly, the heat generated from the device layer 103 can be transmitted from the bonding pad 144 to the diamond layer 152 more efficiently. For example, the diameter D1 of the opening OP1 of the diamond layer 152 ranges from about 40 μm to about 45 μm, and the diameter D2 of the bonding pad 144 ranges from about 50 μm to about 55 μm. In this embodiment, the pitch of the bonding pad 144 may range from about 80 μm to about 90 μm. The disclosure is not limited thereto.

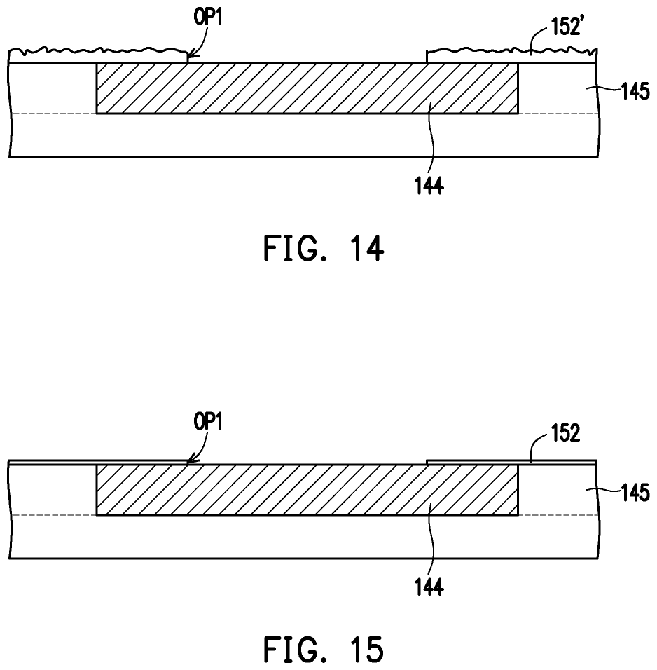

FIG. 14 to FIG. 15 illustrate another one of the possible methods of forming the diamond layer 152, but the disclosure is not limited thereto. It is noted that the semiconductor device in the present embodiment contain many features same as or similar to the semiconductor device disclosed in the previous embodiments. For purpose of clarity and simplicity, detail description of same or similar features may be omitted, and the same or similar reference numbers denote the same or like components.

Referring to FIG. 14, in the embodiments, a diamond layer 152′ may be firstly deposited over the topmost metallization pattern 144 and the dielectric layer 145 of the second interconnect structure. The diamond layer 152′ may be formed by chemically vapor deposition (CVD) process, plasma-Enhanced CVD (PECVD), microwave plasma enhanced chemical vapor deposition (MWCVD), etc. In the embodiment, the diamond layer 152′ may be formed with the opening OP1 exposing a part of the topmost metallization pattern 144. That is, the deposition process may be formed with a patterned mask disposed over the second interconnect structure and covers the regions that the opening OP1 to be formed. Accordingly, the deposition of the diamond would not occur at those regions, so that the diamond layer 152′ can be formed with the opening OP1 revealing the part of the topmost metallization pattern 144. However, the disclosure is not limited thereto. In other embodiments, the diamond layer can be deposited comprehensively over the topmost metallization pattern 144 and the dielectric layer 145, and a patterning process may be performed to form the opening OP1 extending through the diamond layer 152′.

Then, referring to FIG. 15, since the diamond layer 152′ is formed through deposition process, the diamond layer 152′ may have a rough surface as schematically shown in FIG. 14. Accordingly, a planarizing process may then be performed to the diamond layer 152′ to form the diamond layer 152 with a flat top surface before the passivation layer (e.g., the passivation layer 154 in FIG. 13) is formed over the diamond layer 152′. In some embodiments, the planarizing process may include grinding or CMP processes, or other acceptable processes performed on the surface of the diamond layer 152′, and the diamond layer 152 can also be thinned to a predetermined thickness (e.g., thinner than 5 μm) through the planarizing process. It is noted that, with this manufacturing process, the diamond layer 152 would be in direct contact with the topmost metallization pattern 144 and the dielectric layer 145 without the bonding film (e.g., without the bonding film 151 shown in FIG. 13) interposed in between.

FIG. 16 illustrates a cross sectional view of a semiconductor package according to some exemplary embodiments of the present disclosure. Referring to FIG. 6 and FIG. 16, there are a plurality of ways of incorporating the semiconductor device 100 previously disclosed into a semiconductor package. FIG. 16 merely illustrates one of the embodiments for illustrating purposes, and the disclosure is not limited thereto. In the embodiment, the carrier substrate 116 shown in FIG. 6 may be further removed from the semiconductor device 100 and arrives at the semiconductor device 100 shown in FIG. 16, which can be referred to as a first die (or power rail die) 100 to be incorporated into the semiconductor package 10. It is noted that the first die 100 in the present embodiment contain many features same as or similar to the semiconductor device 100 disclosed in the previous embodiments. For purpose of clarity and simplicity, detail description of same or similar features may be omitted, and the same or similar reference numbers denote the same or like components.

Accordingly, the first die 100 includes the device layer 103 disposed between the first interconnect structure 112 and the second interconnect structure 148, the diamond layer 152 disposed over the second interconnect structure 148 and at least revealing a part of the topmost metallization pattern 144 of the second interconnect structure 148, the passivation layer 154 covering the diamond layer 152 and revealing the part of the topmost metallization pattern 144, and a plurality of electrical connectors 158 bonded to the topmost metallization pattern 144.

Accordingly, in the embodiment, the first die 100 may be firstly adhered to a carrier substrate. The carrier substrate may be a glass carrier substrate, a ceramic carrier substrate, or the like. The carrier substrate may be a wafer, such that multiple packages can be formed on the carrier substrate simultaneously. A (front side) redistribution structure 70 having metallization pattern 125 is formed over the carrier substrate.

In some embodiments, a plurality of through vias 20 are formed over the carrier substrate. As an example to form the through vias 20, a seed layer is formed over the redistribution structure 70. In some embodiments, the seed layer is a metal layer, which may be a single layer or a composite layer comprising a plurality of sub-layers formed of different materials. For example, the seed layer may include titanium, copper, molybdenum, tungsten, titanium nitride, titanium tungsten, combinations thereof, or the like. In some embodiments, the seed layer includes a titanium layer and a copper layer over the titanium layer. The seed layer may be formed using, for example, PVD or the like. A photo resist is formed and patterned on the seed layer. The photo resist may be formed by spin coating or the like and may be exposed to light for patterning. The pattern of the photo resist corresponds to the through vias 20. The patterning forms openings through the photo resist to expose the seed layer. A conductive material is formed in the openings of the photo resist and on the exposed portions of the seed layer. The conductive material may be formed by plating, such as electroplating or electroless plating, or the like. The conductive material may include a metal, like copper, titanium, tungsten, aluminum, or the like. The photo resist and portions of the seed layer on which the conductive material is not formed are removed. The photo resist may be removed by an acceptable ashing or stripping process, such as using an oxygen plasma or the like. Once the photo resist is removed, exposed portions of the seed layer are removed, such as by using an acceptable etching process, such as by wet or dry etching. The remaining portions of the seed layer and conductive material form through vias 20. In other embodiments, the seed layer is omitted, and the metallization pattern 125 is used as a seed layer for forming the through vias 20.

The first die 100 is bonded to the redistribution structure 70 with the first interconnect structure 112 facing the redistribution structure 70. In some embodiments, an auxiliary diamond layer 115 may be provided over the redistribution structure 70 before the first die 100 is bonded to the redistribution structure 70, such that the auxiliary diamond layer 115 is disposed between the redistribution structure 70 and the second interconnect structure 148 of the first die 100. The auxiliary diamond layer 115 is thermally coupled to the redistribution structure 70, so as to facilitate the thermal conduction from the device layer 103 of the first die 100 to the redistribution structure 70 through the auxiliary diamond layer 115.

An encapsulating material 30 is formed over the redistribution structure 70 to at least laterally encapsulate the first die 100 and the through vias 20. The encapsulating material 30 may be a molding compound, epoxy, or the like, and may be applied by compression molding, transfer molding, or the like. After curing, the encapsulating material 30 can undergo a grinding process to expose the through vias 20 and the electrical connectors 158. The top surfaces of the through vias 20, the electrical connectors 158, and the encapsulating material 30 are coplanar after the grinding process. Accordingly, the through vias 20 extend through the encapsulating material 30. In some embodiments, the grinding may be omitted, for example, if the through vias 20 and the electrical connectors 158 are already exposed.

A (backside) redistribution structure 40 is formed over the first die 100 and the encapsulating material 30 and electrically connected to the part of the topmost metallization pattern 144 of the second interconnect structure 148 and the plurality of through vias 20. The redistribution structure 40 includes a plurality of metallization patterns and dielectric layers. The metallization pattern and the dielectric layer of the redistribution structure 40 are formed on the encapsulating material 30, the through vias 20, and the electrical connectors 158. With this configuration, the diamond layer 152 is located between the topmost metallization pattern 144 of the second interconnect structure 148 and the redistribution structure 40. The diamond layer 152 is thermally coupled to the topmost metallization pattern 144, so as to facilitate the thermal conduction from the device layer 103 of the first die 100 to the redistribution structure 40 through the diamond layer 152 and dissipate the heat externally through the electrical connectors 42.

Then, the second die 200 is bonded to the first interconnect structure 112 of the first die 100 and the encapsulating material 30 through the redistribution structure 70, and electrically connected to the first interconnect structure 112 and the plurality of through vias 20. In some embodiments, the second die 200 is bonded to the first die 100 using a suitable bonding method, forming a wafer-on-wafer (WoW) structure. In some embodiments, the second die 200 is attached to the first die 100 with bumpless bonds comprising metal-metal bonds, e.g. Cu—Cu bonds, between the conductive pads 125 and 240 and dielectric bonds between the bonding layers, forming a system-on-integrated-chips (SoIC) bond interface.

The second die 200 may include different device regions that are singulated in subsequent steps to form a plurality of integrated circuit packages. The second die 200 may be processed according to applicable manufacturing processes to form integrated circuits. Accordingly, the auxiliary diamond layer 115 is disposed between the second die 200 and the first interconnect structure 112 of the first die 100, so as to transmit the heat generated from the device layer 103 toward the second die 200 through the auxiliary diamond layer 115 and dissipate the heat externally. For example, in some embodiments the second die 200 includes a semiconductor substrate 210, such as silicon, doped or undoped, or an active layer of a semiconductor-on-insulator (SOI) substrate. The semiconductor substrate 210 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GalnP, and/or GaInAsP; or combinations thereof. Other substrates, such as multi-layered or gradient substrates, may also be used. The semiconductor substrate 210 has an active surface, also called a front side, and an inactive surface, also called a back side. A device layer 220 including devices (represented by a transistor) and an inter-layer dielectric (ILD) may be formed at the front surface of the semiconductor substrate 210. The devices 220 may be active devices (e.g., transistors, diodes, etc.), capacitors, resistors, etc. The ILD surrounds and may cover the devices 220. The ILD may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like. The interconnect structure 230 is formed over the ILD. The interconnect structure 230 interconnects the device layer 220 to form an integrated circuit.

The resulting structure may be flipped over, and a plurality of electrical connectors 42 are formed on the redistribution structure 40. The electrical connectors 42 are electrically connected to the second interconnect structure 148 through the bond pad 44 of the redistribution structure 40. The electrical connectors 42 may be BGA connectors, solder balls, metal pillars, controlled collapse chip connection (C4) bumps, micro bumps, electroless nickel-electroless palladium-immersion gold technique (ENEPIG) formed bumps, or the like. The conductive connectors 148 may include a conductive material such as solder, copper, aluminum, gold, nickel, silver, palladium, tin, the like, or a combination thereof. In some embodiments, the electrical connectors 42 are formed by initially forming a layer of solder through such commonly used methods such as evaporation, electroplating, printing solder transfer, ball placement, or the like. Once a layer of solder has been formed on the structure, a reflow may be performed in order to shape the material into the desired bump shapes. In another embodiment, the electrical connectors 42 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the metal pillar connectors 42. The metal cap layer may include nickel, tin, tin-lead, gold, silver, palladium, indium, nickel-palladium-gold, nickel-gold, the like, or a combination thereof and may be formed by a plating process.

FIG. 17 illustrates a cross sectional view of a semiconductor package according to other exemplary embodiments of the present disclosure. Referring to FIG. 17, there are a plurality of ways of incorporating the semiconductor device 100 previously disclosed into a semiconductor package 10a. FIG. 17 illustrates another one of the embodiments for illustrating purposes, and the disclosure is not limited thereto. In the embodiment of FIG. 16, the first die 100 is incorporated into the semiconductor package 10 as a bottom die, and in this embodiment shown in FIG. 17, the first die 100 is incorporated into the semiconductor package 10a as a top die. It is noted that the first die 100 and the semiconductor package 10a in the present embodiment contain many features same as or similar to the first die 100 and the semiconductor package 10 disclosed in the previous embodiments. For purpose of clarity and simplicity, detail description of same or similar features may be omitted, and the same or similar reference numbers denote the same or like components.

In the embodiments, the first die 100 includes the device layer 103 disposed between the first interconnect structure 112 and the second interconnect structure 148, the diamond layer 152 disposed over the second interconnect structure 148 and at least revealing a part of the topmost metallization pattern 144 of the second interconnect structure 148, the passivation layer 154 covering the diamond layer 152 and revealing the part of the topmost metallization pattern 144, and a plurality of electrical connectors 158 bonded to the topmost metallization pattern 144.

Accordingly, in the embodiment, the first die 100 may be firstly adhered to a carrier substrate. The carrier substrate may be a glass carrier substrate, a ceramic carrier substrate, or the like. The carrier substrate may be a wafer, such that multiple packages can be formed on the carrier substrate simultaneously. A redistribution structure 160 is formed over the carrier substrate. In one embodiment, the redistribution structure 160 may include metallization patterns formed therein. The disclosure is not limited thereto. In some embodiments, the auxiliary diamond layer 162 provided over the carrier substrate before the redistribution structure 160 is formed, such that the auxiliary diamond layer 132 is disposed over the redistribution structure 160 and interposed between the carrier substrate and the redistribution structure 160. The auxiliary diamond layer 162 is thermally coupled to the metallization patterns of the redistribution structure 160, so as to facilitate the thermal conduction from the device layer 103 of the first die 100 to external of the package through the auxiliary diamond layer 115.

In some embodiments, a plurality of through vias 20 are formed over the carrier substrate. As an example to form the through vias 20, a seed layer is formed over the redistribution structure 70. In some embodiments, the seed layer is a metal layer, which may be a single layer or a composite layer comprising a plurality of sub-layers formed of different materials. For example, the seed layer may include titanium, copper, molybdenum, tungsten, titanium nitride, titanium tungsten, combinations thereof, or the like. In some embodiments, the seed layer includes a titanium layer and a copper layer over the titanium layer. The seed layer may be formed using, for example, PVD or the like. A photo resist is formed and patterned on the seed layer. The photo resist may be formed by spin coating or the like and may be exposed to light for patterning. The pattern of the photo resist corresponds to the through vias 20. The patterning forms openings through the photo resist to expose the seed layer. A conductive material is formed in the openings of the photo resist and on the exposed portions of the seed layer. The conductive material may be formed by plating, such as electroplating or electroless plating, or the like. The conductive material may include a metal, like copper, titanium, tungsten, aluminum, or the like. The photo resist and portions of the seed layer on which the conductive material is not formed are removed. The photo resist may be removed by an acceptable ashing or stripping process, such as using an oxygen plasma or the like. Once the photo resist is removed, exposed portions of the seed layer are removed, such as by using an acceptable etching process, such as by wet or dry etching. The remaining portions of the seed layer and conductive material form through vias 20. In other embodiments, the seed layer is omitted, and the metallization pattern 125 is used as a seed layer for forming the through vias 20.

The first die 100 is bonded to the dielectric layer 160 with the first interconnect structure 112 facing the dielectric layer 160. An encapsulating material 30 is formed over the redistribution structure 160 to at least laterally encapsulate the first die 100 and the through vias 20. The encapsulating material 30 may be a molding compound, epoxy, or the like, and may be applied by compression molding, transfer molding, or the like. After curing, the encapsulating material 30 can undergo a grinding process to expose the through vias 20 and the electrical connectors 158. The top surfaces of the through vias 20, the electrical connectors 158, and the encapsulating material 30 are coplanar after the grinding process. Accordingly, the through vias 20 extend through the encapsulating material 30. In some embodiments, the grinding may be omitted, for example, if the through vias 20 and the electrical connectors 158 are already exposed. Accordingly, the redistribution structure 160 is disposed over the first interconnect structure 112 of the first die 100 and the encapsulating material 30 and electrically connected to the first interconnect structure 112 and the plurality of through vias 20. The carrier substrate may be removed, and the auxiliary diamond layer 162 is located over the redistribution structure 160.

The second die (bottom wafer) 300 includes through substrate vias (TSVs) 330 embedded in a semiconductor substrate 340. The TSVs 330 may be electrically coupled to conductive lines or other conductive features (not illustrated) of the semiconductor substrate 340 or the device layer 360. The second die 300 includes the device layer 360 including devices (e.g. transistors) electrically coupled to the TSVs 330. The interconnect structure 370 over the device layer 360, and the pads 320 are physically and electrically coupled to the interconnect structure 370. In some embodiments, the TSVs 330 may be electrically coupled to a subsequently formed interconnect structure 380 on the back side of the semiconductor substrate 340.

The second die 300 is bonded to the first interconnect structure 112 of the first die 100 and the encapsulating material 30 through, for example, hybrid bonding process, and the second die 300 is electrically connected to the first interconnect structure 112 and the plurality of through vias 20. In detail, the second die 300 is disposed over the passivation layer 154 of the first die 100 and the encapsulating material 30, and electrically connected to the topmost metallization pattern 144 and the plurality of through vias 20. In some embodiments, the second die 200 is bonded to the first die 100 using a suitable bonding method, forming a wafer-on-wafer (WoW) structure. In some embodiments, the second die 200 is attached to the first die 100 with bumpless bonds comprising metal-metal bonds, e.g. Cu—Cu bonds, between the conductive pads 125 and 240 and dielectric bonds between the bonding layers.

The plurality of electrical connectors 350 are formed on the redistribution structure 380. The electrical connectors 350 may be BGA connectors, solder balls, metal pillars, controlled collapse chip connection (C4) bumps, micro bumps, electroless nickel-electroless palladium-immersion gold technique (ENEPIG) formed bumps, or the like. The electrical connectors 350 may include a conductive material such as solder, copper, aluminum, gold, nickel, silver, palladium, tin, the like, or a combination thereof. In some embodiments, the electrical connectors 350 are formed by initially forming a layer of solder through such commonly used methods such as evaporation, electroplating, printing solder transfer, ball placement, or the like. Once a layer of solder has been formed on the structure, a reflow may be performed in order to shape the material into the desired bump shapes. In another embodiment, the electrical connectors 350 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the metal pillar connectors 350. The metal cap layer may include nickel, tin, tin-lead, gold, silver, palladium, indium, nickel-palladium-gold, nickel-gold, the like, or a combination thereof and may be formed by a plating process.

The electrical connectors 350 may be used for data I/O and power connections to the second die 300 and to the first die 100. The electrical connectors 350 may include controlled collapse chip connection (C4) bumps 356, micro bumps 354, vias 352, ball grid array (BGA) connectors 350, the like, or a combination thereof. In some embodiments, the external connectors may include one type of connector or two or more types of connectors.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the disclosure, a semiconductor device includes a first interconnect structure, a device layer, a second interconnect structure, a diamond layer, a passivation layer, and an electrical connector. The device layer is disposed over the first interconnect structure. The second interconnect structure is disposed over the device layer and includes a topmost metallization pattern. The diamond layer is disposed over the second interconnect structure and at least revealing a part of the topmost metallization pattern. The passivation layer covers the diamond layer and reveals the part of the topmost metallization pattern. The electrical connector is disposed over the passivation layer and bonded to the part of the topmost metallization pattern. In one embodiment, the semiconductor device further includes a dielectric layer covering the passivation layer and the electrical connector bonded to the part of the topmost metallization pattern through the dielectric layer. In one embodiment, a thickness of the diamond layer is substantially equal to and smaller than 20 μm. In one embodiment, the semiconductor device further includes a bonding film disposed between the second interconnect structure and the diamond layer, wherein the bonding film revealing the part of the topmost metallization pattern. In one embodiment, the semiconductor device further includes a carrier substrate bonded to the first interconnect structure. In one embodiment, the semiconductor device further includes an auxiliary diamond layer disposed between the carrier substrate and the first interconnect structure. In one embodiment, the device structure includes a power rail bonded to the second interconnect structure.

In accordance with some embodiments of the disclosure, a semiconductor package includes a first die, an encapsulating material, and a plurality of through vias. The first die includes a device layer, an interconnect structure including a topmost metallization pattern, a diamond layer disposed over the interconnect structure and at least revealing a part of the topmost metallization pattern, and a passivation layer covering the diamond layer and revealing the part of the topmost metallization pattern. The encapsulating material at least laterally encapsulates the first die. The plurality of through vias extend through the encapsulating material. In one embodiment, the interconnect structure further includes a first interconnect structure and a second interconnect structure, the device layer disposed between the first interconnect structure and the second interconnect structure, and the second interconnect structure includes the topmost metallization pattern. In one embodiment, the semiconductor package further includes a redistribution structure disposed over the first die and the encapsulating material and electrically connected to the part of the topmost metallization pattern and the plurality of through vias. In one embodiment, the semiconductor package further includes a plurality of electrical connectors disposed on and electrically connected to the redistribution structure. In one embodiment, the semiconductor package further includes a second die bonded to the first interconnect structure of the first die and the encapsulating material, and electrically connected to the first interconnect structure and the plurality of through vias. In one embodiment, the semiconductor package further includes an auxiliary diamond layer disposed between the second die and the first interconnect structure. In one embodiment, the semiconductor package further includes a redistribution structure disposed over the first interconnect structure and the encapsulating material and electrically connected to the first interconnect structure and the plurality of through vias. In one embodiment, the semiconductor package further includes an auxiliary diamond layer disposed over the redistribution structure. In one embodiment, the semiconductor package further includes a second die disposed over the passivation layer of the first die and the encapsulating material, and electrically connected to the part of the topmost metallization pattern and the plurality of through vias.

In accordance with some embodiments of the disclosure, a manufacturing method of a semiconductor device includes: forming a device layer; forming a first interconnect structure over a first side of the device layer; forming a power rail over a second side of the device layer; forming a second interconnect structure over the power rail, wherein the second interconnect structure includes a topmost metallization pattern; forming a diamond layer over the second interconnect structure, wherein the diamond layer at least revealing a part of the topmost metallization pattern; forming a passivation layer over the diamond layer, wherein the passivation layer reveals the part of the topmost metallization pattern; and providing an electrical connector over the passivation layer, wherein the electrical connector bonded to the part of the topmost metallization pattern. In one embodiment, forming the diamond layer includes: forming a bonding film over the second interconnect structure; attaching a diamond wafer over the second interconnect structure through the bonding film; performing a thinning process to form a thinned diamond wafer; performing a patterning process on the thinned diamond wafer and the bonding film to form the diamond layer and the bond film revealing the part of the topmost metallization pattern. In one embodiment, forming the diamond layer includes: depositing a diamond layer over the second interconnect structure, wherein the diamond layer reveals the part of the topmost metallization pattern. In one embodiment, forming the diamond layer further includes: performing a planarizing process to the diamond layer before the passivation layer is formed over the diamond layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first interconnect structure;
a device layer disposed over the first interconnect structure;
a second interconnect structure disposed over the device layer and comprises a topmost metallization pattern;
a diamond layer disposed over the second interconnect structure and at least revealing a part of the topmost metallization pattern;
a passivation layer covering the diamond layer and revealing the part of the topmost metallization pattern; and
an electrical connector disposed over the passivation layer and bonded to the part of the topmost metallization pattern.

2. The semiconductor device as claimed in claim 1, further comprising a dielectric layer covering the passivation layer and the electrical connector bonded to the part of the topmost metallization pattern through the dielectric layer.

3. The semiconductor device as claimed in claim 1, wherein a thickness of the diamond layer is substantially equal to and smaller than 20 μm.

4. The semiconductor device as claimed in claim 1, further comprising a bonding film disposed between the second interconnect structure and the diamond layer, wherein the bonding film revealing the part of the topmost metallization pattern.

5. The semiconductor device as claimed in claim 1, further comprising a carrier substrate bonded to the first interconnect structure.

6. The semiconductor device as claimed in claim 5, further comprising an auxiliary diamond layer disposed between the carrier substrate and the first interconnect structure.

7. The semiconductor device as claimed in claim 1, wherein the device structure comprises a power rail bonded to the second interconnect structure.

8. A semiconductor package, comprising:
a first die comprising:
a device layer;
an interconnect structure comprising a topmost metallization pattern;
a diamond layer disposed over the interconnect structure and at least revealing a part of the topmost metallization pattern; and
a passivation layer covering the diamond layer and revealing the part of the topmost metallization pattern; and
an encapsulating material at least laterally encapsulating the first die; and
a plurality of through vias extending through the encapsulating material.

9. The semiconductor package as claimed in claim 8, wherein the interconnect structure further comprises a first interconnect structure and a second interconnect structure, the device layer disposed between the first interconnect structure and the second interconnect structure, and the second interconnect structure comprises the topmost metallization pattern.

10. The semiconductor package as claimed in claim 8, further comprising a redistribution structure disposed over the first die and the encapsulating material and electrically connected to the part of the topmost metallization pattern and the plurality of through vias.

11. The semiconductor package as claimed in claim 10, further comprising a plurality of electrical connectors disposed on and electrically connected to the redistribution structure.

12. The semiconductor package as claimed in claim 9, further comprising a second die bonded to the first interconnect structure of the first die and the encapsulating material, and electrically connected to the first interconnect structure and the plurality of through vias.

13. The semiconductor package as claimed in claim 12, further comprising an auxiliary diamond layer disposed between the second die and the first interconnect structure.

14. The semiconductor package as claimed in claim 9, further comprising a redistribution structure disposed over the first interconnect structure and the encapsulating material and electrically connected to the first interconnect structure and the plurality of through vias.

15. The semiconductor package as claimed in claim 14, further comprising an auxiliary diamond layer disposed over the redistribution structure.

16. The semiconductor package as claimed in claim 14, further comprising a second die disposed over the passivation layer of the first die and the encapsulating material, and electrically connected to the part of the topmost metallization pattern and the plurality of through vias.

17. A manufacturing method of a semiconductor device, comprising:
forming a device layer;
forming a first interconnect structure over a first side of the device layer;
forming a power rail over a second side of the device layer;
forming a second interconnect structure over the power rail, wherein the second interconnect structure comprises a topmost metallization pattern;
forming a diamond layer over the second interconnect structure, wherein the diamond layer at least revealing a part of the topmost metallization pattern;
forming a passivation layer over the diamond layer, wherein the passivation layer reveals the part of the topmost metallization pattern; and
providing an electrical connector over the passivation layer, wherein the electrical connector bonded to the part of the topmost metallization pattern.

18. The manufacturing method of the semiconductor device as claimed in claim 17, wherein forming the diamond layer comprises:
forming a bonding film over the second interconnect structure;
attaching a diamond wafer over the second interconnect structure through the bonding film;
performing a thinning process to form a thinned diamond wafer;
performing a patterning process on the thinned diamond wafer and the bonding film to form the diamond layer and the bond film revealing the part of the topmost metallization pattern.

19. The manufacturing method of the semiconductor device as claimed in claim 17, wherein forming the diamond layer comprises:
depositing a diamond layer over the second interconnect structure, wherein the diamond layer reveals the part of the topmost metallization pattern.

20. The manufacturing method of the semiconductor device as claimed in claim 19, wherein forming the diamond layer further comprises:
performing a planarizing process to the diamond layer before the passivation layer is formed over the diamond layer.
